(19) United States
(12) Patent Application Publication
(10) Pub. No.: US 2024/0260208 A1
(43) Pub. Date: Aug. 1, 2024

(54) DEVICES FOR SHIELDING COMPONENTRY OF AN ELECTRICAL GRID

(71) Applicant: MICATU INC., Horseheads, NY (US)

(72) Inventors: Michael Oshetski, Horseheads, NY (US); James Kennedy, Corning, NY (US); David Burdick, Corning, NY (US); Atul Pradhan, Pittsford, NY (US)

(21) Appl. No.: 18/422,143

(22) Filed: Jan. 25, 2024

Related U.S. Application Data
(60) Provisional application No. 63/481,662, filed on Jan. 26, 2023.

(51) Int. Cl. H05K 5/02

(52) U.S. Cl. CPC H05K 5/0209

(57) ABSTRACT

A sunshield can protect internal componentry against temperature fluctuation rates. The shield can include a housing. The housing can include two similar halves. Each half can include a vertical wall with two vertical edges. The vertical edges of one half can be configured to mate, directly or indirectly, with the vertical edges of the other half to form a single unit. The single unit can be shaped to correspond with the exterior shape of the internal componentry. The shield can have an air gap between the vertical walls and the internal componentry.

### CROSS-REFERENCE TO RELATED APPLICATION(S)

This application claims priority to U.S. Provisional Patent Application No. 63/481,662, filed Jan. 26, 2023, the contents of which are incorporated herein by reference.

### TECHNICAL FIELD

The present disclosure relates to devices in an electrical grid. More particularly, the present technology is related to the technical field of shielding componentry, such as monitoring equipment, deployed in an electrical grid.

### BACKGROUND

Power utilities have increasing requirements for electrical grids as technology and the increased need for electricity advance. Grids are often subjected to extreme temperature changes. Various componentry utilized in grids modern, such as current and voltage sensors and condition monitors, can be negatively impacted by high temperatures and fluctuations in temperature.

### SUMMARY

In one aspect, the disclosed embodiments provide a sunshield can protect internal componentry against temperature fluctuation rates. The shield can include a housing. The housing can include two similar halves. Each half can include a vertical wall with two vertical edges. The vertical edges of only half can be configured to mate, directly or indirectly, with the vertical edges of the other half to form a single unit. The single unit can be shaped to correspond with the exterior shape of the internal componentry. The shield can have an air gap between the vertical walls and the internal componentry.

In some embodiments, the internal componentry can include a sensor. The sensor can include a voltage sensor and/or a current sensor.

In other embodiments, a shield can include vertical wall having a tapered, a bottom flange, and/or a rib. A bottom flange can be configured for attaching a shield to, for example, a baseplate via screws or bolts. A rib can extend from a tapered top to a bottom flange.

In yet other embodiments, a shield can be made of cycloaliphatic epoxy. The epoxy can include additives and/or fillers. In other embodiments, the shield can be made of various materials, including epoxies, plastics, and/or metals; the shield can also include surface treatments to improve radiant shielding and/or alter thermal conductivity, electrical conductivity, and/or electrical susceptibility.

Embodiments can include various air gaps between an inner wall of the shield and an outer housing wall of internal componentry. In a preferred embodiment, the air gap is around half an inch. Other gaps can be utilized. For example, the gap can be between 0.25 and 6 inches, 0.25 and 2 inches, 0.25 and 1 inches, or 0.25 and 0.75 inches.

In other embodiments, a shield can include a connecting means for connecting the shield to internal componentry. Various connecting means described herein can be configured to facilitate adjusting the shield's position with respect to internal componentry. The shield can include a sealing means, which can be disposed between vertical edges of the two halves of the shield, which can facilitate adjusting the shield's position with respect to the two halves.

In yet other embodiments, the innermost portion of a tapered top can be considered a ring (of various shapes). The ring can be of smaller dimension than the internal componentry's outermost dimension.

Another aspect of the invention can include a sunshield. The sunshield can be made of cycloaliphatic epoxy. The epoxy structure can be molded into a half-cylinder shape. The structure can have a top taper, a bottom flange, and a rib extending from the top taper to the bottom flange.

In some embodiments, the half-cylinder shape is an elliptic-cylindrical shape.

In other embodiments, a bottom flange can have one or more holes. The holes can be utilized for attaching a sunshield to a sensor housing, for example, via screws or bolts. The structure can be installed such that it shields the sensor housing from direct sunlight.

In yet other embodiments, the sunshield can include a second structure of cycloaliphatic epoxy molded into a second half-cylinder shape. The second structure can include a top taper, a bottom flange, and/or a rib. The rib can extend from the top taper to the bottom flange.

### BRIEF DESCRIPTION OF THE DRAWINGS

The present invention is further described in the detailed description, which follows, in reference to the noted plurality of drawings by way of non-limiting examples of certain embodiments of the present invention, in which like numerals represent like elements throughout the several views of the drawings, and wherein:

FIG. 1 depicts an isometric view of a shield.

FIG. 2 depicts an internal isometric view of a shield.

FIG. 3 depicts a left internal view of a shield.

FIG. 4 depicts a front view of a right half of a shield.

FIG. 5 depicts a top view of a right half of a shield.

FIG. 6 depicts a bottom view of a right half of a shield.

FIG. 7 depicts a cross-section of an assembled shield.

FIG. 8 depicts a bottom view of an assembled shield.

FIG. 9 depicts a shield deployed on an electrical grid monitor.

FIG. 10 depicts a shield deployed on an electrical grid monitor.

FIG. 11 depicts a molds for casting two halves of a shield.

FIG. 12 depicts a plot of both temperature and ramp rate with and without a shield.

### DETAILED DESCRIPTION

A detailed explanation of the apparatus, systems, methods, and exemplary embodiments of the present invention are described below. Numerous specific details are set forth in order to provide a thorough understanding of embodiments of the invention. However, it will be understood by ordinary artisans that embodiments of the present invention may be practiced without these specific details. In other instances, well-known methods, procedures, and components have not been described in detail so as not to obscure the present invention. Exemplary embodiments described, shown, and/or disclosed herein are not intended to limit any claim, but rather, are intended to instruct the ordinary artisan as to various aspects of the invention. Other embodiments can be practiced and/or implemented without departing from the scope and spirit of the invention.

One of the challenges that power utilities face is the impact of extreme temperatures on the various componentry used in modern electrical grids. For example, current and voltage sensors are critical components that are used to measure and control the flow of electricity in the grid. They are often exposed to high temperatures, as well as fluctuations in temperature, which can affect their accuracy and reliability. Similarly, condition monitors are used to monitor the health and performance of various components in the grid, and they too can be negatively impacted by extreme temperatures.

Various approaches can be utilized to mitigate such challenges. For example, temperature-resistant materials and/or design strategies can be utilized in the construction of componentry. Thermal management technologies, such as cooling systems and insulation, can be utilized to protect sensitive equipment from extreme temperatures. Practicalities of implementation, costs, and other considerations of various approaches should can dictate which avenues are appropriate for a given situation. There are several factors to consider when choosing the right type of heat shielding for a particular application. These can include the intensity and duration of the heat exposure, the type of material or structure being protected, and the location and environment of the housing. It is important to carefully assess these factors and choose a heat shielding housing that is appropriate for the specific needs and requirements of the application. The ability to effectively manage the temperature of their electrical grid componentry can be critical for ensuring the reliability and performance of the grid.

A type of heat shielding is a radiant barrier. The structure can reflect and/or absorb radiant heat energy, rather than insulating against it. There are several different types of heat shielding, each of which is suited to specific applications and environments. For example, radiant barriers can be made from a variety of materials, such as plastic, epoxy, aluminum, reflective paint, or special coatings.

An approach can include a housing-type structure to provide radiant shielding against temperature fluctuation rates, for example fluctuations caused by sunshine. The heat shielding can be shaped to correspond to the componentry being shielded, and may include features such as a taper around the top, ribs for rigidity and support, and flanges for attaching the housing to the interior componentry. The housing may be installed in a location that is exposed to temperature fluctuations, such as sunshine, and may be adjustable to allow for optimal positioning. By effectively managing the temperature of the electrical grid componentry, the reliability and performance of the grid can be ensured.

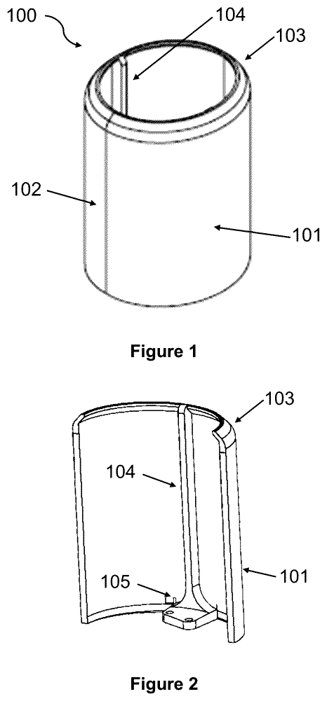

FIG. 1 illustrates an embodiment of a sunshield (100). The embodiment can include largely similar right (101) and left (102) halves configured to mate and form shape corresponding to the componentry being shielded, here an elliptic-cylindrical shape. By corresponding in shape, it is not necessary nor intended that the shield walls are to match each surface feature of the internal componentry, but rather that the walls generally match the largest overall outer dimensions of the componentry. Greater correspondence, however, in the detailed shape of the componentry is of course possible with the understanding that it can, for example with vertical changes in relief, negatively impact convection flow rate described herein. The halves can each include a taper (103) around the top of the shield. Each half can include a rib (104) to provide to provide rigidity and/or support. The rib can be further reinforced by flaring at its top and/or bottom where it meets, respectively, the taper and a flange.

FIG. 2 illustrates an isometric internal view of the right half of the shield. As shown, the shield can include a flange (105) for attaching the shield to a baseplate. The left half can include a similar flange. Other connecting means for attaching the shield to internal componentry can be utilized. For example, the vertical walls can include embossing or protrusions having screw/bolt holes, such embossments or protrusions can be sized to determine the air gap. Similarly, the sidewalls can include holes for screws or bolts, and spacers can be utilized to stand off the shield from the internal componentry. Flanges, clips, or hangers can be employed, for example, at the top of the shield. Similar to the rib, a flange can be further reinforced by flaring of material where it meets the sidewall.

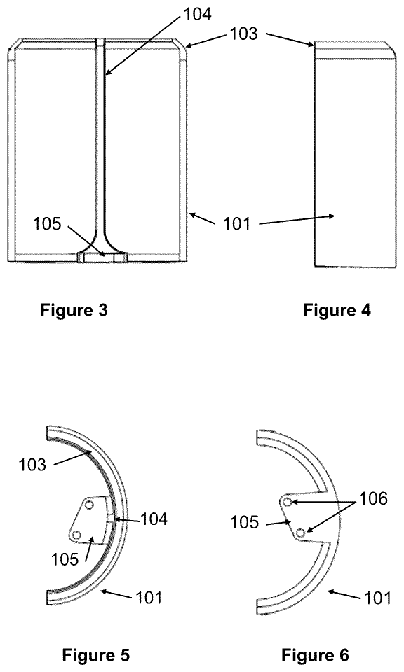

FIG. 3 illustrates a left internal view of the shield. A taper (103) can be of greater or lesser degrees and of greater or lesser depth and/or size as preferred by the skilled artisan. The taper can help mitigate airborne debris and snow from falling in between the sunshield and protected componentry. In a preferred embodiment, the taper is designed such that the ring it makes is smaller in size than the outer shape of the internal componentry but of an angle to not significantly decrease airflow.

FIG. 4 illustrates a front view of a right half of the shield. While the shield is shown as having a substantially cylindrical wall, other shapes corresponding to the shape of internal componentry can be utilized.

FIG. 5 illustrates a top view of a right half of the shield. As shown, the flange (105) can extend from the shield wall toward the bottom-center of the shield. FIG. 6 illustrates a bottom view of the right half of the shield. Screw or bolt holes (106) in the flange can facilitate attachment of the shield to the componentry. The screw or bolt holes can be of various configurations. For example, they can be round holes, they can be elongated to allow adjustment of the shield, or a combination.

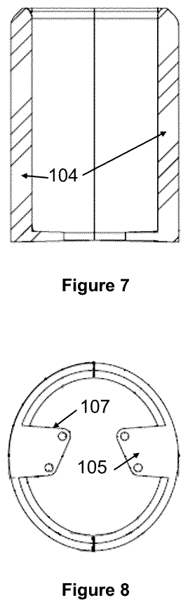

FIG. 7 illustrates a cross-section of the assembled shield. The cross-section bisects the assembled shield through ribs (104).

FIG. 8 illustrates a bottom view of the assembled shield. The right-half flange (105) is mirror-imaged to the left-half flange (107). Other shapes are, however, possible, for example to correspond to features of the protected internal componentry. The right-half and left-half shields can also be substantially identical. That can have multiple advantages. For example, the angled flanges can be extended to a mating position with one another, the number of molds used to create the shields can be reduced, and the number of replacement parts can be reduced.

It can be important for creating and maintaining convection that the vertical edges of the two halves of the sunshield be connected. The two halves can simply abut one other at their vertical edges and be held together via attaching screws in the flanges at the bottom of the sensor body. Additional sealing means can be utilized, such as silicon or adhesive. Mechanical sealing, such as a gasket or other sealing means, can also be utilized between the vertical edges of the halves to increase adjustability of the sunshield, for example, allowing the two halves to be mounted somewhat further apart.

Absolute sealing need not be required. For example, as described herein, a sunshield with solid housing walls can reduce thermal ramp rates by about 55%. A substantially similar sunshield with small holes throughout the walls can reduce thermal ramp rates by about 45%. That relatively minor reduction shows that sealing of the two halves need not be vital for acceptable performance and that not sealing and/or including apertures in the sidewalls can be an advantageous tradeoff against other considerations, e.g. allowing some lateral airflow to improve evaporation and sublimation rates under various circumstances.

While a preferred embodiment can include an open top, the top of a sunshield can be closed and/or sealed with the internal componentry. Sealing the top can provide similar performance as a shield with small holes. Empirically, a design with a closed top can be around 20% less efficient at cooling than an open design.

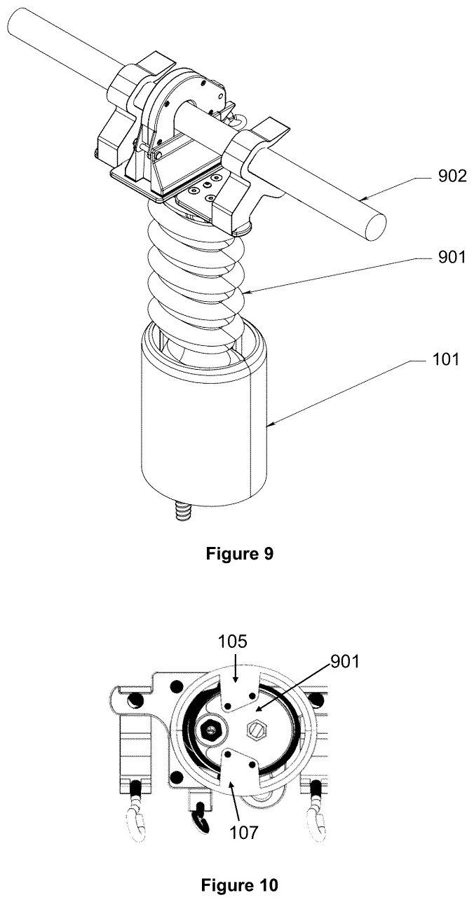

FIG. 9 illustrates a shield deployed in the field. The shield (101) can be positioned about the sensitive componentry of an electrical grid monitor (901) which is attached to powerline (902).

FIG. 10 illustrates the flanges of the shield attached to a baseplate on the bottom portion of the electrical grid monitor. The view illustrates the airflow spacer between the shield and the internal componentry. The configurate can facilitate convection and can significantly reduce temperature rise and gradient that the interior assembly, e.g. an optical assembly internal to a sensor body, experiences. That can minimize thermal stresses and prevent shock.

A key purpose of a sunshield can be mitigating temperature spikes in internal optical components. The open design described herein can facilitate natural convection to freely release hot air in between the sunshield and body. Thus, although there are no moving parts, the configuration can create actual active cooling. The sunshield can induce convection currents that move cooler air from the bottom to the top which cools the body.

Air gap dimensions can be an important consideration. For example, a sunshield with a half-inch air gap can reduce thermal ramp rates by 55%. Increasing the air gap increases the size and weight of the sunshield. Generally, smaller air gaps can perform worse because the air flow between the sunshield and body decreases, thus not allowing hot air to freely escape.

In a preferred embodiment, the sunshield can be made of cycloaliphatic epoxy, a type of epoxy resin that is characterized by its high thermal stability and chemical resistance. This material can work well because it is both thermally and electrically insulative as well as weather resistant. The material is also useful because it can be injection molded. Injection molding is a versatile process that can be used to produce parts with complex shapes and high levels of precision. Injection molding is particularly well-suited for mass production, as it allows for the efficient production of large quantities of identical parts.

The injection molding process can begin with designing the protective housing, for example using a 3D computer-aided design (CAD) model of the part, as well as determining the material properties and design requirements. Once the design of the protective housing has been determined, a next step can be to design and construct the mold.

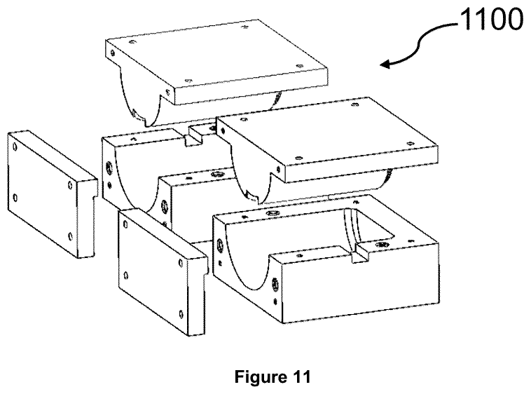

FIG. 11 illustrates two three-part molds (1100) that can be utilized to form the right (101) and left (102) halves of the sunshield described herein. In a preferred embodiment, the molds are of aluminum. The mold is typically made from metal and is designed to be able to withstand the high pressures and temperatures of the injection molding process.

The epoxy can be prepared and mixed it with any preferred additives or fillers. The material can be injected into the mold under high pressure, using a specialized injection molding machine. As the material solidifies, it takes on the shape of the mold cavity, forming the protective housing. The solidified protective housing can be removed from the mold by a specialized tool or by simply opening the mold. The parts can undergo additional post-processing steps, such as trimming, grinding, and/or polishing, to remove any excess material and achieve the desired surface finish. The parts can be treated with a surface to improve radiant shielding.

Embodiments described herein that mitigate temperature spike can be beneficial to generally all voltage and current sensors because temperature directly affects voltage and current measurements. In general, heat shielding housing should be designed to be as effective as practical, being as efficient and cost-effective as possible. This can involve using a combination of different materials and techniques, such as insulation and reflective coatings. There are several ways to improve the effectiveness of shielding. Some of these can include using high-quality, high-performance materials that are specifically designed for shielding, ensuring that the housing is properly designed and constructed to fit the specific needs and requirements of the application, and/or using multiple layers or layers of different materials to provide additional protection. For example, in an alternative embodiment, the sunshield can be a one-sided shield, substantially similar to the right half or left half described herein, which can be deployed only on the sun-facing side of the componentry. Such embodiments can encircle more or less of the componentry as is dictated by incident sunlight throughout the year (e.g. only placing the shield on the south side of the componentry in northern latitudes).

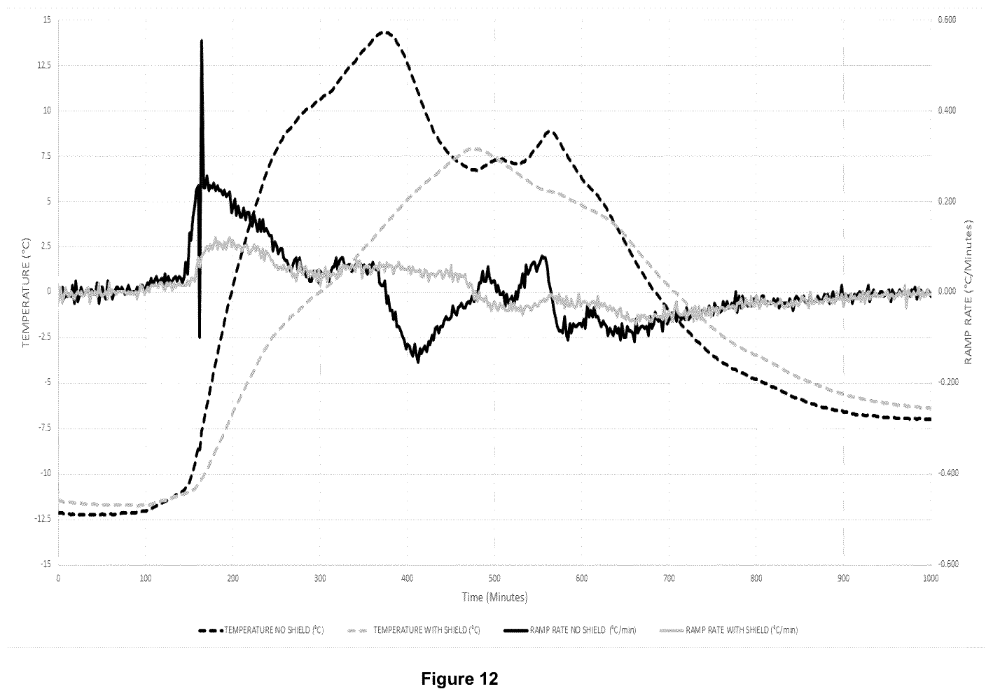

FIG. 12 shows the reduction in temperature of the componentry with the use of the shield as well as reduction of the temperature ramp rate. Temperature ramp rates with the use of a shield can be limited to or below +/−0.1° C./min. Without the shield rates can exceed greater than 0.2° C./min and exhibit temperature ramp rate spikes above 0.5° C./min. Such sudden temperature ramp spikes can seriously stress and damage the componentry, which would otherwise benefit from the alleviation of thermal stress with use of the shield.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

1. A shield for protecting internal componentry against temperature fluctuation rates, comprising:
a housing having a first half and a second half;
the first half and the second half each having a vertical wall, wherein the vertical wall has vertical edges, and wherein the vertical edges of the first half are configured to mate, directly or indirectly, with the vertical edges of the second half to form a single unit;
the single unit shaped to correspond with the internal componentry; and
a gap between the vertical wall and the internal componentry.

2. The shield of claim 1, wherein the vertical wall comprises a tapered top.

3. The shield of claim 1, wherein the vertical wall comprises a bottom flange.

4. The shield of claim 1, wherein the vertical wall comprises a rib.

5. The shield of claim 1, wherein the vertical wall comprises a tapered top, a bottom flange for attaching the shield to a baseplate via screws or bolts, and a rib extending from the tapered top to the bottom flange.

6. The shield of claim 1, wherein the first half and the second half comprise cycloaliphatic epoxy.

7. The shield of claim 1, wherein the gap is between 0.25 and 2 inches.

8. The shield of claim 7, wherein the gap is between 0.25 and 1 inches.

9. The shield of claim 8, wherein the gap is between 0.25 and 0.75 inches.

10. The shield of claim 1, further comprising a connecting means for connecting the shield to the internal componentry, wherein the connecting means is configured to allow adjustment of the positioning of the shield with respect to the internal componentry.

11. The shield of claim 10, further comprising a sealing means disposed between the vertical edges of the two halves to allow adjustment of the positioning of the shield with respect to the two halves.

12. The shield of claim 1, wherein the tapered top's innermost portion is a ring of smaller dimension than the internal componentry's outermost dimension.

13. The shield of claim 1, wherein the internal componentry comprises a voltage sensor.

14. The shield of claim 1, wherein the internal componentry comprises a current sensor.

15. A sunshield, comprising:
a structure of cycloaliphatic epoxy;
the structure being molded into a half-cylinder shape; and
the structure having a top taper, a bottom flange, and a rib extending from the top taper to the bottom flange.

16. The sunshield of claim 15, wherein the half-cylinder shape is an elliptic-cylindrical shape.

17. The sunshield of claim 16, wherein the bottom flange has one or more holes for attaching the sunshield to a sensor housing via screws or bolts.

18. The sunshield of claim 17, wherein the structure is installed such that it shields the sensor housing from direct sunlight.

19. The sunshield of claim 17, further comprising a second structure of cycloaliphatic epoxy molded into a second half-cylinder shape having a second top taper, a second bottom flange, and a second rib extending from the second top taper to the second bottom flange.
